(19) United States
(12) Patent Application Publication
(10) Pub. No.: US 2002/0173088 A1
(43) Pub. Date: Nov. 21, 2002

(54) Method of forming a MOS transistor on a semiconductor wafer

(76) Inventors: Hua-Chou Tseng, Hsin-Chu City (TW); Tony Lin, Hsin-Chu City (TW); Kuan-Lun Cheng, Kao-Hsiung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/840,993

(22) Filed: Apr. 25, 2001

(51) Int. Cl. H01L 21/335; H01L 21/8232

(52) U.S. Cl. 438/199; 438/234; 438/258

(57) ABSTRACT

The present invention provides a method of forming a metal-oxide-semiconductor (MOS) transistor on a surface of a substrate of a semiconductor wafer. A gate is firstly formed in a predetermined area on the surface of the substrate. A first ion implantation process using group VA elements as dopant is performed thereafter to form a first doped area in portions of the substrate adjacent to either side of the gate. By performing a second ion implantation process immediately after the first ion implantation process using group VIIIA or group IVA elements as dopant, a second doped area is formed in portions of the substrate adjacent to portions of the substrate under the first doped area. After depositing a rapid-thermal chemical vapor deposition (RTCVD) dielectric layer that covers both the substrate and the gate, a spacer on either side of the gate is finally formed by etching back the RTCVD dielectric layer.

### BACKGROUND OF THE INVENTION

1. Field of the Invention

The present invention relates to a method of forming a metal-oxide-semiconductor (MOS) transistor on a substrate of a semiconductor wafer, and more specifically, to a method of forming a MOS transistor with a low substrate current.

2. Description of the Prior Art

A metal-oxide semiconductor (MOS) is a commonly used electrical device in integrated circuits. With the increasing sophistication in the fabricating process, the size of these units has decreased, and consequently so has their channel length that is defined as the distance between the source/drain and the substrate of the MOS transistor. However, when the channel length is too short, detrimental effects including short channel effect and hot carrier effect can occur that affect functions of the MOS transistor.

The short channel effect, leading to a threshold voltage (Vₜ) roll-off, and the hot carrier effect, leading to an undesired substrate current (I_{sub}) or even to an electrical breakdown, can seriously impede the performance of the MOS transistor. A lightly doped drain (LDD) implantation process, also called source/drain extension (SDE) implantation process, is currently employed to resolve the short channel effect. By performing the LDD implantation process to form a LDD area in portions of the source/drain adjacent to the channel, the electric field between the source and drain is altered.

Besides, rapid thermal chemical vapor deposition (RTCVD), a substitution of the commonly applied low pressure CVD (LPCVD) process, is frequently employed as well to form a spacer so as to eliminate the short channel effect. Please refer to FIG. 1 of the comparison diagram between Vₜ roll-off curves of PMOS transistors formed by the RTCVD spacer method and the LPCVD spacer method, respectively. As shown in FIG. 1, the x-axis corresponds to the after-etch-inspect (AIE) critical dimension (CD), measured in micrometers (μm), of the polysilicon gate and the y-axis corresponds to Vₜ measured in volts. As implied by FIG. 1, the RTCVD spacer method leads to significant improvement when applied on a PMOS transistor, having a thinner gate oxide layer, in a core circuit.

However, the rapidly increased temperature in the RTCVD process leads to a larger electrical field formed on the interface between the LDD area and the substrate of the NMOS transistor doped with heavy dopants, including phosphorus (P) and arsenic (As), so as to generate a greater substrate current that often occurs on the NMOS transistor having a thicker gate oxide layer in an input/output (I/O) circuit. Please refer to FIG. 2 of the comparison diagram between I_{sub} curves of I/O-NMOS transistors formed by the RTCVD spacer method and the LPCVD spacer method, respectively. As shown in FIG. 2, the x-axis corresponds to the source-drain current (I_{sd}), measured in μA/μm, and the y-axis corresponds to the substrate current I_{sub}. As shown in FIG. 2, the I/O-NMOS transistor formed by the RTCVD spacer method has the higher substrate current. This is due to the inconsistent concentration distribution of heavy dopants in the LDD area of the NMOS transistor formed by the RTCVD spacer method.

### SUMMARY OF THE INVENTION

It is therefore a primary object of the present invention to provide a method of forming a metal-oxide-semiconductor (MOS) transistor on a surface of a substrate of a semiconductor wafer so as to reduce the substrate current of the MOS transistor.

It is another object of the present invention to provide a method of forming a MOS transistor with an improved threshold voltage (Vₜ) roll-off curve and a low substrate current by performing both a lightly doped drain (LDD) implantation process and a rapid-thermal chemical vapor deposition (RTCVD) process.

In the method provided in the present invention, a gate is firstly formed in a predetermined area on the surface of the substrate. A first ion implantation process using group VA elements as dopant is performed thereafter to form a first doped area in portions of the substrate adjacent to either side of the gate. By performing a second ion implantation process immediately after the first ion implantation process using group VIIIA elements, including argon (Ar), or group IVA elements, including silicon (Si) and germanium (Ge), as dopant, a second doped area is formed in portions of the substrate adjacent to portions of the substrate under the first doped area. After depositing a rapid-thermal chemical vapor deposition (RTCVD) dielectric layer that covers both the substrate and the gate, a spacer on either side of the gate is finally formed by etching back the RTCVD dielectric layer.

It is an advantage of the present invention against the prior art that a LDD ion implantation process, a VIIIA/IVA ion implantation process and a source/drain ion implantation process are performed respectively. Silicon lattice defects or vacancies can be formed under or on the edge of the LDD area by performing the ion implantation of group VIIIA/IVA elements so that the concentration uniformity of the phosphorus atoms in the LDD area can be increased in the subsequent RTA activation process. The inconsistent concentration distribution of the dopant is thus prevented and the substrate current is relatively reduced.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWING

FIG. 1 is the comparison diagram between Vₜ roll-off curves of PMOS transistors formed by an RTCVD spacer method and an LPCVD spacer one, respectively.

FIG. 2 of the comparison diagram between I_{sub} curves of I/O-NMOS transistors formed by the RTCVD spacer method and the LPCVD spacer one, respectively.

FIG. 3 to FIG. 8 are the cross-sectional views of forming a metal-oxide semiconductor (MOS) transistor on a semiconductor substrate according to the preferred embodiment of the present invention.

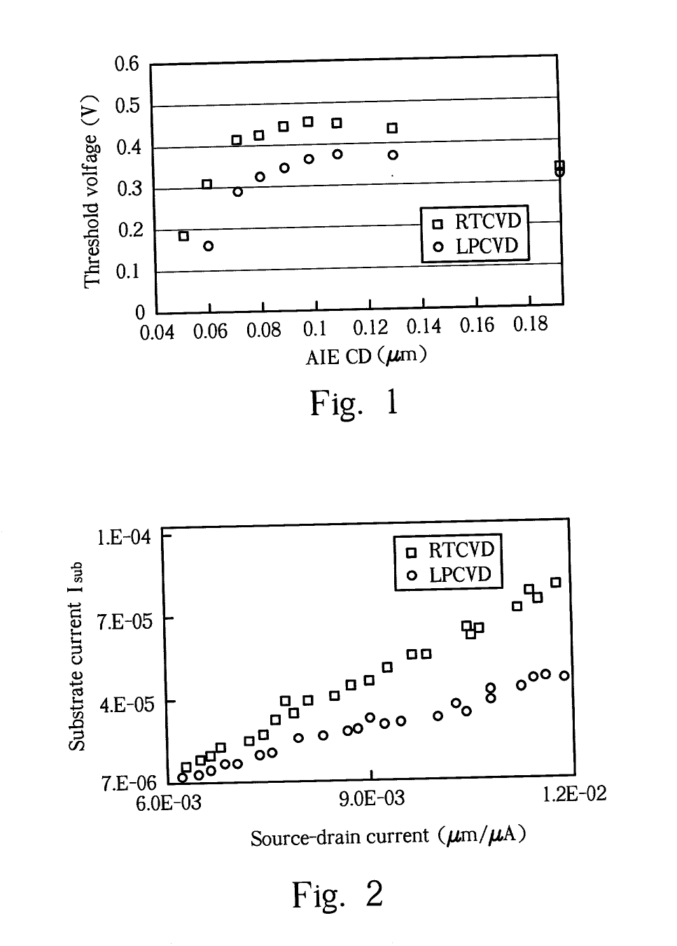

### DETAILED DESCRIPTION OF THE PREFERRED EMBODIMENT

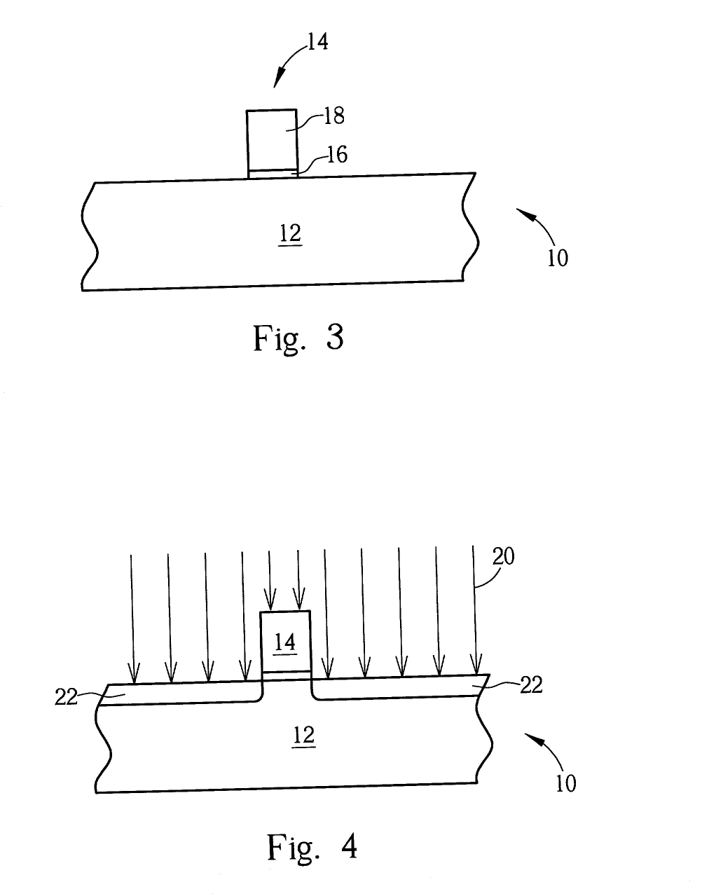

Please refer to FIG. 3 to FIG. 8 of cross-sectional views of forming a metal-oxide semiconductor (MOS) transistor 60 on a semiconductor substrate 10 according to the preferred embodiment of the present invention. In the preferred embodiment of the present invention illustrated in FIG. 3 to FIG. 8, the semiconductor substrate 10 is a 15-25 ohm-cm P-type doped silicon substrate of a <100> crystal lattice orientation and the MOS transistor 60 is a NMOS transistor, more specifically, an I/O-NMOS transistor. The NMOS transistor normally has a thicker gate oxide layer and higher substrate current generated. Alternatively, the method provided in the present invention can be applied not only on I/O-NMOS transistors but also on other MOS transistors, including PMOS transistor, CMOS transistor and BiCMOS transistor. One of ordinary skill in the art can apply the method of the present invention on MOS transistors with different electrical performances so as to obtain equivalent results of the present invention.

In FIG. 3 to FIG. 8, only a p-well area 12, on which the MOS transistor 60 is fabricated, of the semiconductor substrate 10, for simplicity is shown. In the preferred embodiment of the present invention, the p-well area 12 is formed in an I/O circuit area and isolated by a shallow trench isolation (STI) structure (not shown). As shown in FIG. 3, a gate 14, comprising a gate oxide layer 16 positioned on the surface of the semiconductor substrate 10 and a doped silicon gate conductive layer 18 positioned atop the gate oxide layer 16, is firstly formed on portions of the surface of the semiconductor substrate 10 in the p-well area 12. The gate oxide layer 16 is composed of silicon oxide and formed by performing a dry/wet thermal oxidation process.

As shown in FIG. 4, a first ion implantation process 20, using phosphorus (P) atoms as dopants, is then performed to form a lightly doped drain (LDD) in portions of the semiconductor substrate 10 adjacent to either side of the gate 14. The implantation dosage of phosphorus is no less than 1×10^{14 cm}⁻², with implantation energy no greater than 20 KeV. Alternatively group VA elements including arsenic (As) can be used as dopants for the first implantation process 20.

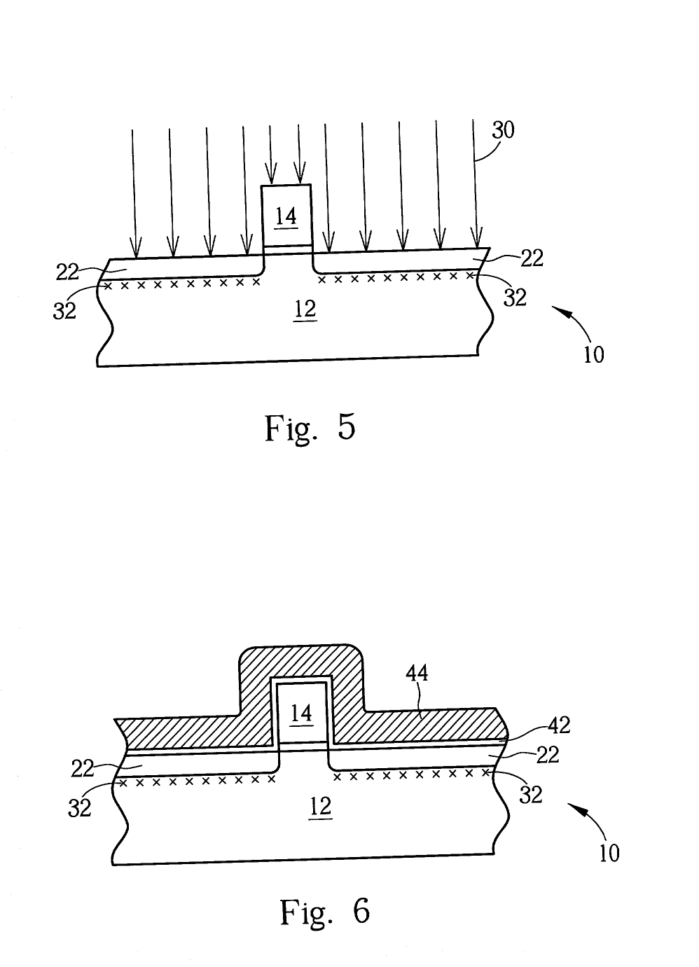

As shown in FIG. 5, a second ion implantation process 30, using group IVA or group VIIIA elements as dopants, is performed immediately after the first ion implantation process 20 to form a pocket-shaped doped area 32 in portions of the semiconductor substrate 10 adjacent to portions of the semiconductor substrate 10 under the LDD 22. The preferred dopants for the second ion implantation process include argon (Ar) in the range of 1.0E14 to 5.0E16 cm⁻², with an implantation energy in the range of 5 to 60 KeV, silicon (Si) in the range of 1.0E14 to 5.0E16 cm², with an implantation energy in the range of 5 to 80 KeV, and germanium (Ge). With the implantation of Ar, Si or Ge atoms, silicon lattice defects or vacancies can be formed under or on the edge of the LDD area 22. The silicon lattice defects can increase the concentration uniformity of the phosphorus atoms in the LbD area 22 in the subsequent processes so as to prevent the inconsistent concentration distribution of dopants.

As shown in FIG. 6, a silicon oxide liner layer 42, with a thickness in the range of 100 to 300 angstroms, and a silicon nitride layer 44, with the approximate thickness of 1000 angstroms, are formed on the surface of the semiconductor substrate 10, to evenly cover the surfaces of the semiconductor substrate 10 and the gate 14. The silicon oxide liner layer 42 is formed by chemical vapor deposition (CVD), including a low-pressure CVD (LPCVD) process. The silicon nitride layer 44 is formed by performing a rapid-thermal CVD (RTCVD) process, using ammonia (NH₄) and dichlorosilane (SiCl₂H₂) as reacting gases, under the preferred temperature of 700 to 800° C. . The flow rates of NH₄ and SiCl₂H₂ are 1 standard liter per minute (slpm) and 30 to 50 standard cubic centimeters per minute (sccm) respectively.

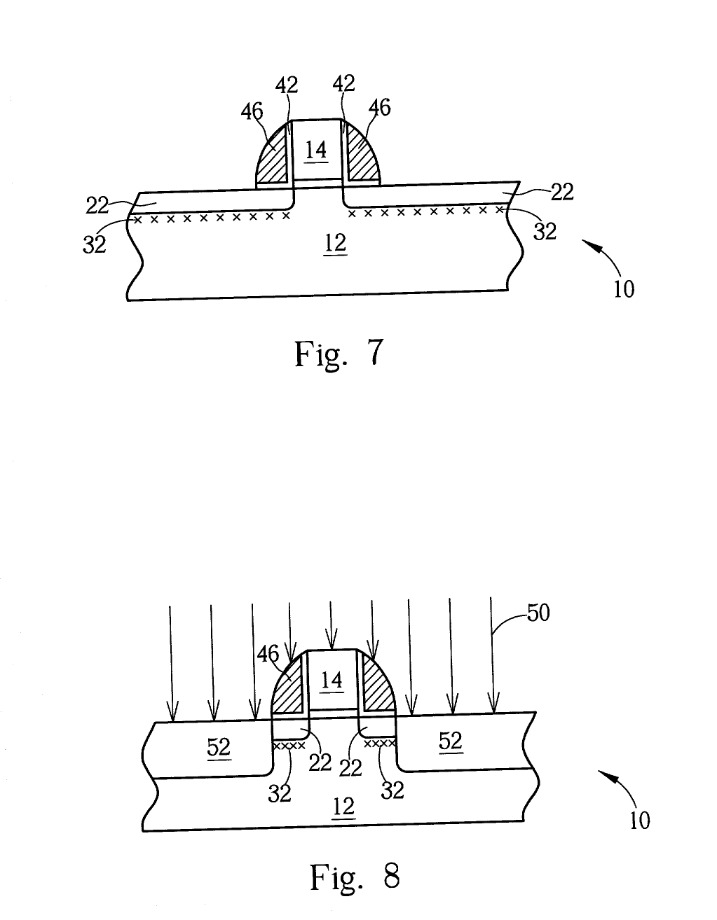

As shown in FIG. 7, an anisotropic dry etching process is performed to evenly etch the silicon nitride layer 44 and the silicon oxide liner layer 42 down to the surface of the p-well area 12 so as to form a spacer 46, composed of the residual portions of the silicon nitride layer 44, on either side of the gate 14. As shown in FIG. 8, a N⁺ ion implantation process 50, using phosphorus or arsenic (As) in the range of 1.0E14 to 1.0E16 cm², with an implantation energy in the range of 10 to 80 KeV, as dopants, is performed to form a source/drain 52 in portions of the p-well area 12 under either side of the spacer 46.

As shown in FIG. 9, the production of the MOS transistor 60 is finally completed by performing a rapid thermal annealing (RTA) process in a temperature of 900 to 1150° C. after the N⁺ ion implantation process 50 to activate the previously doped ions so as to achieve the required concentrations in the LDD area 22 and the source/drain 52 respectively, as well as to fix the defected surface of the semiconductor substrate 10 due to the ion implantation processes. The pocket-shaped doped area 32 formed by the second ion implantation process 30 can increase the concentration uniformity of the LDD area 22 after the RTA process so as to reduce the substrate current of the MOS transistor 60.

Optionally, a self-alignment silicide (salicide) process is often performed to reduce the contact resistance of silicon surfaces of the gate 14 and the source/drain 52 of the MOS transistor 60. A tungsten (W) metal layer (not shown) is firstly formed on the surface of the semiconductor substrate 10 to cover the surfaces of the gate 14 and the source/drain 52. A thermal process is then performed to form a tungsten silicide (Wsiₓ) layer on the surfaces of the gate 14 and the source/drain 52 via the reaction between the tungsten metal layer, and the gate 14 and the source/drain 52. The unreacted portions of the tungsten metal layer are finally removed by performing a wet etching process.

In comparison to the prior art, the method of the present invention is to perform a LDD ion implantation process, a VIIIA/IVA ion implantation process and finally a source/drain ion implantation process. With the ion implantation of group VIIIA/IVA elements, silicon lattice defects or vacancies can be formed under or on the edge of the LDD area. The silicon lattice defects can increase the concentration uniformity of the phosphorus atoms in the LDD area in the subsequent RTA activation process so as to prevent the inconsistent concentration distribution of the dopants, and reduce the substrate current. Besides, the method of the present invention can also eliminate the short channel effect as the RTCVD method does.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of forming a metal-oxide-semiconductor (MOS) transistor on a surface of a substrate of a semiconductor wafer, the method comprising:
forming a gate on the surface of the substrate;
performing a first ion implantation process to form a first doped area in portions of the substrate adjacent to either side of the gate;
performing a second ion implantation process immediately after the first ion implantation process to form a second doped area in portions of the substrate adjacent to portions of the substrate under the first doped area;
depositing a rapid-thermal chemical vapor deposition (RTCVD) dielectric layer that covers both the substrate and the gate; and
etching back the RTCVD dielectric layer to form a spacer on either side of the gate;
wherein the second doped area is doped with group VIIIA or group IVA elements, and the second ion implantation process increases concentration uniformity of the dopants in the first doped area so as to reduce a substrate current of the MOS transistor.

2. The method of claim 1 wherein the first doped area is doped with group VA elements to form a source/drain extension (SDE) region of the MOS transistor.

3. The method of claim 2 wherein phosphorus is used for the group VA elements.

4. The method of claim 3 wherein the implantation dosage of the phosphorus is no less than 1×10¹⁴ cm⁻², with an implantation energy no greater than 20 KeV.

5. The method of claim 2 wherein phosphorus (P) or arsenic (As) are used for the group VA elements.

6. The method of claim 1 wherein argon (Ar) is used for the group VIIIA elements.

7. The method of claim 1 wherein silicon (Si) or germanium (Ge) are used for the group IVA elements.

8. The method of claim 1 wherein a gate insulation layer and a gate conductive layer are positioned atop the gate respectively.

9. The method of claim 1 wherein the RTCVD dielectric layer is an RTCVD silicon nitride layer.

10. A method of forming an NMOS transistor, the method comprising:
providing a silicon substrate with a gate positioned on a surface of the silicon substrate;
performing a VA ion implantation process with dopants from elements in the VA group to form an n-type doped area in portions of the silicon substrate adjacent to either side of the gate;
performing a VIIIA/IVA ion implantation process with dopants from the VIIIA or IVA group to form a pocket doped area in portions of the silicon substrate adjacent to portions of the silicon substrate under the n-type doped area;
depositing a RTCVD dielectric layer that covers both the silicon substrate and the gate;
etching back the RTCVD dielectric layer to form a spacer on either side of the gate;
performing a source/drain (S/D) ion implantation process to form an S/D doped area in portions of the silicon substrate adjacent to either side of the gate; and
performing an S/D rapid thermal annealing (RTA) process to activate the dopants implanted into the SID doped area;
wherein the VIIIA/IVA ion implantation increases concentration uniformity of the dopants in the n-type doped area so as to reduce a substrate current of the NMOS transistor.

11. The method of claim 10 wherein the n-type doped area is a source/drain extension (SDE) region of the NMOS transistor.

12. The method of claim 10 wherein the dopants in the VA ion implantation process are phosphorus atoms.

13. The method of claim 12 wherein the implantation dosage of the phosphorus atoms is no less than 1×10¹⁴ cm⁻², with an implantation energy no greater than 20 KeV.

14. The method of claim 10 wherein the dopants in the VIIIA/IVA ion implantation process are elements from the VIIIA group, including argon.

15. The method of claim 10 wherein the dopants in the VIIIA/IVA ion implantation process are elements in the IVA group, including silicon and germanium.

16. The method of claim 10 wherein the RTCVD dielectric layer is a RTCVD silicon nitride layer.
